(19) United States
(12) Patent Application Publication
(10) Pub. No.: US 2003/0070610 A1
(43) Pub. Date: Apr. 17, 2003

(54) Method and device for producing group III-N, group III-V-N and metal-nitrogen component structures on Si substrates

(76) Inventors: Armin Dadgar, Berlin (DE); Alois Krost, Berlin (DE); Michael Heuken, Aachen (DE); Assadulah Alam, Aachen (DE); Oliver Schon, Herzogenrath (DE)

Correspondence Address: ST. ONGE STEWARD JOHNSTON & REENS, LLC, 986 BEDFORD STREET, STAMFORD, CT, 06905-5619, US

(21) Appl. No.: 10/233,647

(22) Filed: Sep. 3, 2002

Related U.S. Application Data
(63) Continuation of application No. PCT/DE01/00777, filed on Mar. 2, 2001.

(30) Foreign Application Priority Data
Mar. 2, 2000 (DE) 100 09 945

(51) Int. Cl. C30B 23/00; C30B 25/00; C30B 28/14; C30B 28/12

(52) U.S. Cl. 117/104

(57) ABSTRACT

The invention relates to a method and a device for producing Group-III-N, Group-III-V-N and metal-nitrogen component structures on Si substrates by means of organometallic gas phase epitaxy. The inventive method and the corresponding device are characterized in that a low-temperature germination layer and/or a low-temperature buffer layer is/are produced from a Group-III-V semiconductor and/or a metal-Group-V connecting semiconductor and a component layer or sequence of layers is produced from Group-III-N, Group-III-V-N or metal-Group-V semiconductors in a horizontal growth chamber, in that a minimal lateral temperature difference of less than 5K, preferably less that 1K, an adjustable roof temperature and/or wall temperature and a temperature on a substrate holder that is caused to rotate by a gas cushion are maintained, the reaction gases being introduced in such a way as to prevent any unwanted interaction between the starting gases and in such a way that the procedure can be observed without disturbing the growth process.

This application is a continuation of pending International Application No. PCT/DE01/00777 filed on Mar. 2, 2001, which designates the United States and claims priority of German Application No. 100 09 945 filed on Mar. 2, 2000.

### FIELD OF THE INVENTION

The invention relates to a method for producing group III-N, group III-V-N and metal-nitrogen component structures on Si substrates and to a corresponding device.

### BACKGROUND OF THE INVENTION

Homoepitaxy on GaN substrates is not possible on commercial scales on account of the currently low size and quality of the available GaN substrates according to the prior art. Therefore, the commercial production of group III nitride layers, as are required for example for blue and green light-emitting diodes, is at present carried out mainly on sapphire and SiC substrates. However, the substrate costs are in this case so high that they are responsible for an appreciable part of the component costs [Duboz, as in the case of the citations which follow, see the bibliography for the reference]. For an explanation of all the details not described here any more specifically, reference is expressly made to this and all other literature references cited hereafter.

The production of group III-N component layers on lower-cost substrates can therefore significantly reduce the costs of the components. What is more, if insulating sapphire is used as a substrate, for example in the case of light-emitting diodes, complex structuring is necessary for the rear-side contacting of the components, as described for example by Mayer et al. [Mayer].

Large-area growth on sapphire and SiC is currently not possible owing to a lack of available substrates; this has an adverse effect on the yield per unit area, since, as a result of the unusable wafer edge of several millimeters, the yield is always smaller in the case of small substrate diameters than in the case of large diameters.

On account of the availability of substrates of up to currently 30 cm in diameter, growth on Si currently offers the possibility of increasing the yield with low-cost substrates and, in the case of many components, also of allowing easier structuring than on sapphire. Furthermore, as a result, easy integration is also possible with the existing Si technology.

Therefore, at present great efforts are generally made to deposit group III-N layers on Si substrates. In this respect, growth on Si (111) areas is favored [Auner, Guha, Kobayashi, Nikishin, Sánchez-Garcia, Schenk, Tran]. Alternatively, growth with optimized parameters on Si (100) areas [Wang] and in particular on Si (100) structured with (111) V-shaped trenches is possible, as described in DE 197 25 900 A1.

A general problem of epitaxy of nitridic semiconductors on Si is the nitriding of the substrate [Ito, Nikishin, Tran]. In MOCVD, for growth on Si, different approaches are adopted to avoid nitriding the substrate; generally a protective low-temperature layer is provided on the Si substrate. However, investigations by the authors mentioned above so far generally do not go beyond basic feasibility studies. For instance, the feasibility of an LED structure on Si was recently demonstrated by Guha et al. and Tran et al. [Guha, Tran].

For a high yield of components, not only is use of the largest possible substrates necessary but also great homogeneity of the layers. For instance, a layer thickness variation in the monolayer range with an active InₓGa₁₋ₓN quantum-well layer, as used for example in LEDs, can lead to a shift of the maximum emission wavelength by several nanometers. In the case of lasers, such a variation in the wavelength is completely unacceptable. In addition to this, in the case of such a component there is also the problem of keeping a check on the indium concentration, which strongly depends on the deposition temperature and the temperature of the surrounding walls. However, the low-temperature seed and buffer layers on the Si substrate must have best possible homogeneity, in order for the layer lying over them to have a consistent quality over the wafer.

### SUMMARY OF THE INVENTION

The invention is based on the object of providing a method and a device for the low-cost production of group III-N and group III-V-N components on Si substrates.

A solution according to the invention for achieving this object is provided in the independent claims, respectively directed at a method and at a device.

According to the invention, in a way known per se, use is made of a horizontal MOCVD reactor which, as a result of the construction of the growth chamber and the rotating susceptors, ensures great homogeneity and reproducibility of the deposited layers. Possible embodiments of such MOCVD reactors are described below. In this case, the advantage of the susceptors rotating on a gas cushion is the improved homogeneity of the layers with virtually non-existent abrasion. In the case of other, mechanically driven systems, the abrasion causes particles, which can adversely influence the layer growth or the purity of the layers. Use of the MOCVD systems used according to the invention and of Si substrates makes possible the low-cost production of group III-N components with a high component yield and little use of source materials. The efficiency of the group III elements, Ga for example, is in this case over 10% in a multi-wafer reactor. In particular in the case of growth of ternary or quaternary layers, such as InGaN for example, it is very important to keep an exact check not only on the substrate temperature but also on the temperature of the surrounding walls and the ceiling of the growth chamber to obtain a high level of reproducibility and homogeneity, since the incorporation depends very much on these parameters.

According to the invention, a special gas inlet geometry is therefore used, distinguished by the fact that undesired cross-reactions between the gases do not take place. The special temperature profile in the reactor and the temperature management and control system is designed in such a way that any interactions of the gases are suppressed, so that reproducibility is ensured and the efficiency of the starting materials is increased.

The use of a low-temperature seed layer and/or buffer layer makes possible uniform seeding or growing of the substrate in the MOCVD system described. The device is therefore designed in such a way that a precise check can be kept on the static and dynamic temperature distribution on the Si substrates. The temperature interval is 300-1600° C. This system is necessary both for the seed layer and for the active layers. A seed layer is understood here as meaning a three-dimensional layer a few nanometers thick, which is not necessarily a closed layer, or three-dimensional islands, which in spite of possibly poor crystalline and/or stoichiometric properties, serves as a basis for the subsequent layer growth or from which the further layer growth emanates. In the case of epitaxy on Si, it is also often necessary to predetermine by this means a preferential orientation from the non-polar Si to the, for example, polar GaN, and consequently to allow the buffer or component layer to be deposited on it in the first place. However, with skilled choice of the depositing parameters, growth on Si is also possible, for example, directly with a low-temperature buffer layer as the first layer. Such seed and/or buffer layers on Si are—according to the invention—of great significance for the successful growth of group II-N and group III-V-N layers on Si. This is so because only a closed seed and/or buffer layer, for example of a group III-V material such as material in the system AlₓGa_{y}In_{z}NₐAs_{b}P_{c} (x+y+z=1, a+b+c=1) for example, can avoid nitriding of the substrate at relatively high temperatures. In this case, “low temperature” always means, dependent on the metal, a temperature below the customary growth temperature of nitridic semiconductors such as GaN and AlN, which in MOCVD lies above 1000° C. Also of advantage for the growth of a seed or buffer layer are the developments according to the invention in which the prior deposition of a metal, such as for example Al, serves the purpose of protecting the Si surface from the disturbing nitriding before the introduction of NH₃, for example [Ito, Nikishin].

The method according to the invention is made possible on large-area substrates or in multi-wafer installations by the homogeneity of the layers deposited in these installations, since a uniformly thick seed and/or buffer layer is necessary for example to avoid Si nitriding in partial regions of the substrate being caused by a seed and/or buffer layer that is too thin in places. Furthermore, the homogeneity of the seed and/or buffer layer, of inferior value from the crystalline viewpoint, is important to ensure a uniform quality of the applied layers over a large area. If the thickness is inhomogeneous, the seed and/or buffer layer does not crystallize uniformly at relatively high temperatures and then leads to fluctuations in the crystalline quality, and consequently, for example in the case of LED structures, to fluctuations in the light yield over wide regions of the wafer.

Serving for monitoring the layer growth is the advantageously used in-situ measurement of the reflectivity. Exemplary embodiments of such in-situ reflectivity measurements are described in more detail in connection with the drawings. This allows the thickness and composition of the layer to be monitored during growth, and adapted for example if there is a possible small drift in the parameters, so that the layers produced in this way remain usable, or for example a decision can be taken before the end of growth as to whether the layers are to be grown further or further processed later. In particular, reflectivity measurement is very helpful in the case of growth of the low-temperature seed layer and/or the low-temperature buffer and of the group III-N layer deposited on the seed or buffer layer at relatively high temperatures. The layer thickness and the smoothness or closed formation of the deposited layers can be assessed here very well. For instance, under NH₃ or other nitrogen starting materials which are used for example for the nitrogen component in group III-N layer growth, Si has a nitriding tendency at relatively high temperatures. However, no growth of, for example, crystalline group III-N layers is possible on such nitrided Si. This usually results in the growth of no material or polycrystalline material, which has a changed or low reflectivity, which can be observed in the measurement. If, for example, as a result of poor pretreatment of the substrate or poor substrate quality, the, for example, group III-N layer deposited on it is not nitrided with a closed formation, the underlying Si partly reaches down below the already deposited layer and consequently leads to an unusable component structure. One of the ways in which this can be detected at an early time is by the measurement of the reflectivity, claimed in one of the developments according to the invention, so that the layer growth is ended in time and consequently costs are saved. Drawings are shown by way of example in conjunction with the exemplary embodiments. Only adapted process control and suitable reactor geometry provide technically usable layer deposition. A corresponding representation which meets these requirements is contained in the description of the figures.

Possible ways in which a reduction in the dislocation density and crack formation in the applied component layer can be achieved by varying the layer and growth parameters are provided in the subclaims. These possibilities can be used individually, in combination or else multiply and in multiple combination. Since Si and, for example, GaN have different lattice constants and crystal lattices, one effect of this is that dislocations occur at the interface. The thermal lattice mismatch of these materials additionally leads to the formation of cracks from a layer thickness of about 1 μm, for example during cooling of the layer [Monemar] or during growth when setting different temperatures, for example for InGaN growth and AlGaN or GaN. During the growth of such layers, for example for InGaN/GaN multi-quantum-well structures, in MOCVD growth the temperature often varies by several hundred degrees Celsius. Nikishin et al. have shown that, during growth in MBE, the formation of cracks can be avoided by the growth of a seed or buffer layer of, for example, AlN produced alternately from metal and subsequent nitriding [Nikishin]. In this case, there does not necessarily have to be a stoichiometric ratio of group III to group V constituents in this layer. The materials mentioned in a subclaim also include what are known as layer lattices, such as WSe₂ for example, which are soft in one direction, i.e. have slip planes. As a result, it is possible to deposit on them layers which have few dislocations and few cracks. The conversion of a seed and/or buffer layer on Si substrates during or after the deposition of, for example, AlAs by oxidation into Al₂O₃, as carried out by Kobayashi et al., can also serve as a basis for the subsequent layer growth [Kobayashi].

To eliminate dislocations, Li et al. have shown that, by partial masking of a group III nitride layer using methods such as ELO, ELOG and LEO, the layer deposited on it has fewer dislocations, at least above the masked regions [Li]. Multiple combination of this method can lead to layers with few dislocations over a large area. Furthermore, by applying such masks with a suitable coefficient of expansion, the formation of cracks in the deposited group III nitride layer can be reduced. The reduction in the dislocation density can also be brought about by the growth of low-temperature intermediate layers, described by Iwaya et al. [Iwaya]. The author describes how the dislocation density is greatly reduced by such layers, which require no further processing, that is to say can be deposited in one step with the component. By skilled choice of the material in such intermediate layers, such as for example the relatively hard AlN and/or for example the comparatively soft InN, and the correct choice of the depositing parameters of such layers, the thermally caused stressing, and consequently crack formation, can also be eliminated or reduced.

Since the Si band gap is only about 1.1 eV, but the photon energies generated by a component based for example on GaN are usually significantly above that, a considerable part of the emitted photons is absorbed in the Si, by contrast with the use of sapphire substrates. To avoid or reduce this, the methods described in further subclaims can be used. In one method according to one of the advantageous developments, for example, a metal of adequate thickness is applied to the substrate by means of vaporizing, sputtering or vapor-phase deposition and the reflectivity is increased as a result. Here, careful choice of the metal, for example, is a prerequisite for subsequently being able to deposit high-grade crystalline layers. In this case, high-quality overgrowth is made possible preferably by applying partial masking, that is to say for example of SiO₂ and/or SiNₓ or metal strips, made for example of W, on, for example, an AlN or a GaN seed or buffer layer, and subsequent overgrowth, as described for example by Kawaguchi et al. [Kawaguchi]. The method according to the invention serves in an advantageous way for eliminating dislocations. This masking can also be provided multiply and also in offset arrangement, so that the efficiency of this layer as a reflector but also as a means of improving the material is increased.

In the case of a further—preferred—development, according to the invention, two aims with respect to increasing the light intensity can be pursued. On the one hand, making the upper interface non-reflective for the corresponding optical wavelength by applying one or more layers with different refractive indices and/or with respect to the epitaxial layer and/or the surrounding medium, which is usually air or in the case of an LED often a plastic. On the other hand, the combination of two Bragg mirrors for producing a vertical light beam. Here, for example, the combination with the development provided in a subclaim is also very suitable for the lower mirror.

Exact maintenance of the layer thickness—in particular in the case of vertically emitting lasers—is important in the case of transparent layers, that is to say usually non-metallic layers, for increasing reflection. This homogeneity can usually be ensured over large areas by using sputtering techniques. If, however, vapor-phase deposition is the technique in question, this is possible over a large surface area only with the system according to the invention. An exemplary embodiment of a light-emitting GaN structure on an Si substrate with a suitable buffer layer is likewise represented the of the description of exemplary embodiments.

According to one development of the method according to the invention, more simple contact technology and lower resistances in the region of p-doped layers are made possible if layer structures are deposited on this p-conducting Si substrate.

According to a further method, intermediate layers may be provided between the silicon substrate and active components for optimum adaptation to the respective task or use of the component structure to be produced.

### BRIEF DESCRIPTION OF THE DRAWINGS

The invention is described below by way of example, without restricting the general idea of the invention, on the basis of exemplary embodiments with reference to the drawing, to which you are moreover expressly referred with regard to the disclosure of all details according to the invention not explained more specifically in the text. In the drawing:

FIG. 1 shows a cross-section through an MOCVD reactor for the coating of GaN compounds on a 2-inch silicon wafer,

FIG. 2 shows a cross-section through a multi-wafer MOCVD reactor for the coating of a number of silicon wafers with GaN compounds,

FIG. 3 shows a detail of the windows for observing the growth

FIGS. 4a, b, c show exemplary reflectivity measurement of GaN on an Si wafer, and

FIG. 5 shows a GaN LED produced according to the invention on silicon and the measured spectrum of the light emission.

### DETAILED DESCRIPTION OF DRAWINGS

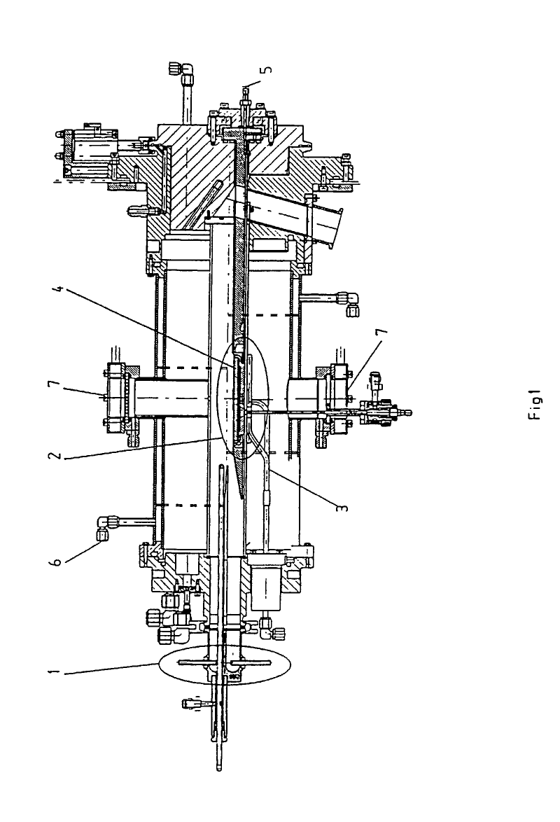

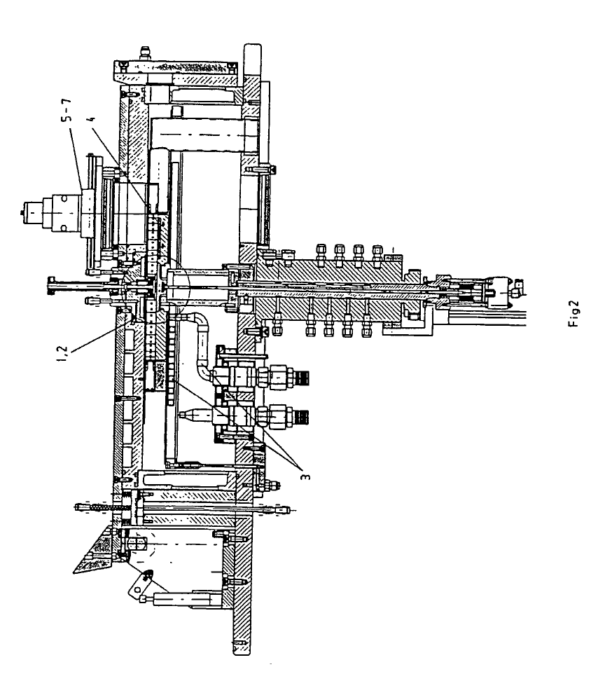

FIG. 1 shows a cross-section through an MOCVD reactor used within the scope of the invention for the coating of GaN compounds on (for example) 2-inch silicon wafers. 1 designates a gas inlet, with which gases for the production of a layer or buffer layer or the reflective layer are introduced into the reaction chamber. 2 designates the region in which a substrate 4 on a rotating susceptor on a gas cushion and the gas inlet arrangement for avoiding nitriding of the Si substrate are disposed. For heat-treating the substrate 4, a coil 3 is provided, producing adequate temperature homogeneity at 300° C., 530° C., 700° C., 1000° C., 1100° C. and at 1600° C.

5 designates a lead-through for keeping a check on the substrate temperature. Reference numeral 6 designates thermostatic control of the ceiling and the walls. Reference numeral 7 designates optical windows for an in-situ measurement.

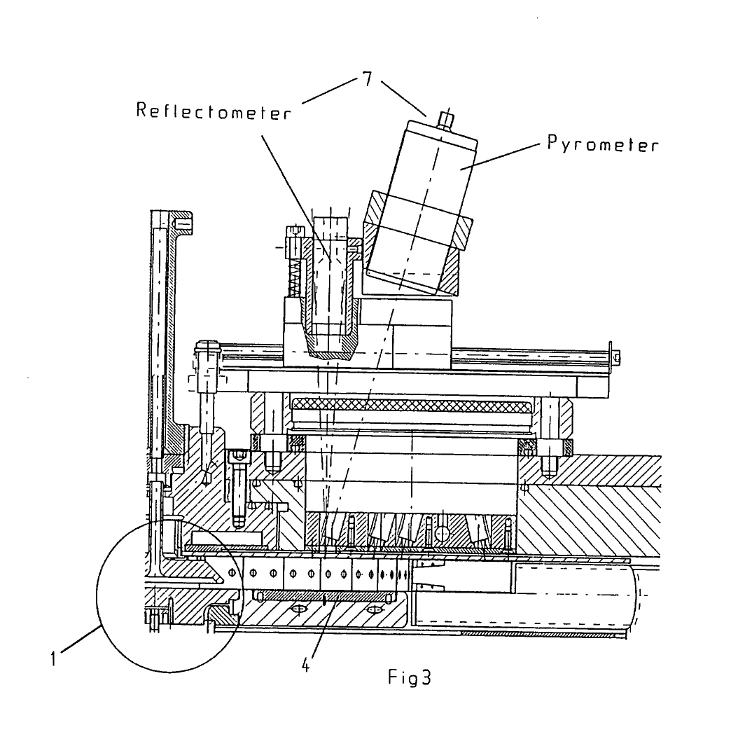

FIG. 2 shows a cross-section through a further exemplary embodiment of a multi-wafer MOCVD reactor for the coating of a number of silicon wafers with GaN compounds.

Reference numeral 1 designates a special gas inlet for a layer or buffer layer or the reflective layer.

Reference numeral 2 designates a substrate and a gas inlet arrangement for avoiding nitride loading of the Si substrate. Reference numeral 3 designates a coil with adequate temperature homogeneity simultaneously at 300° C., 530° C., 700° C., 1000° C. and 1100° C., 1600° C. Reference numeral 4 designates a rotating susceptor on a gas cushion. Reference numeral 5 designates a lead-through for keeping a check on the substrate temperature. Reference numeral 6 designates thermostatic control of the ceiling and the walls. Reference numeral 7 designates optical windows for an in-situ measurement.

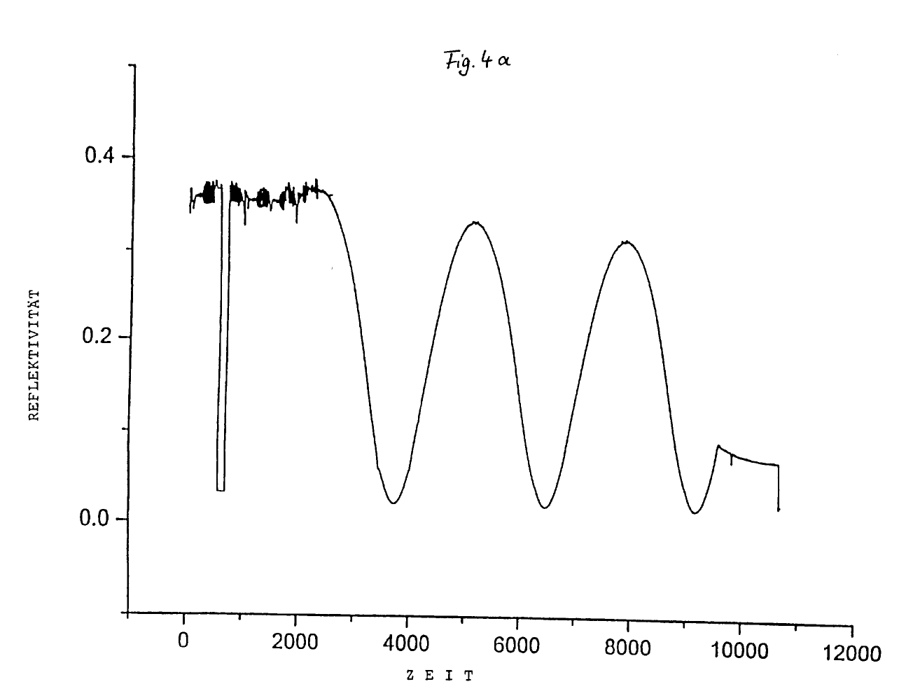

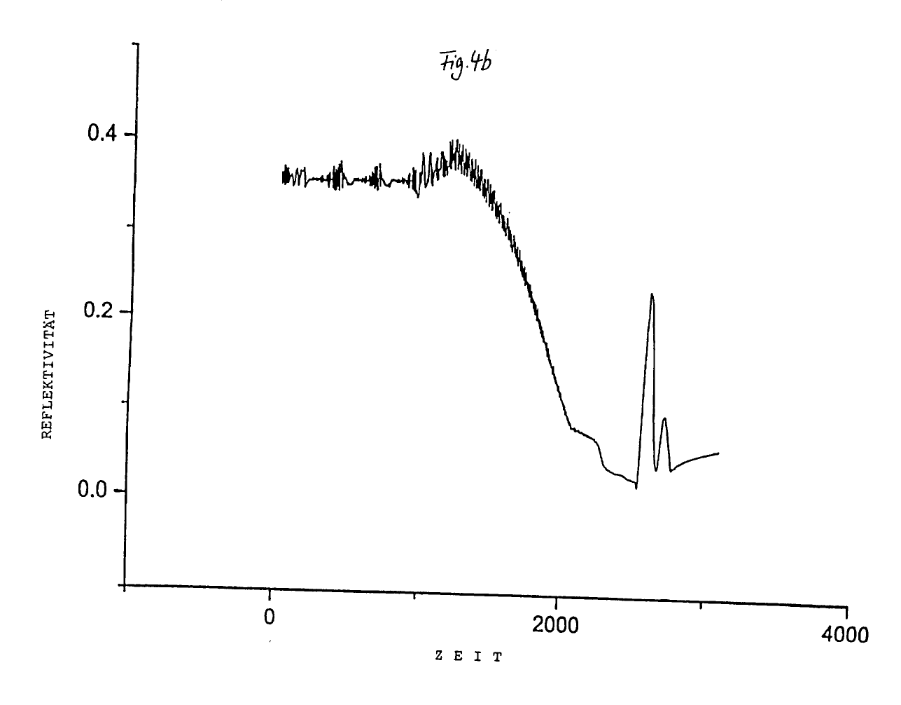

FIG. 3 shows an exemplary embodiment of a detail of the windows for observing the growth.

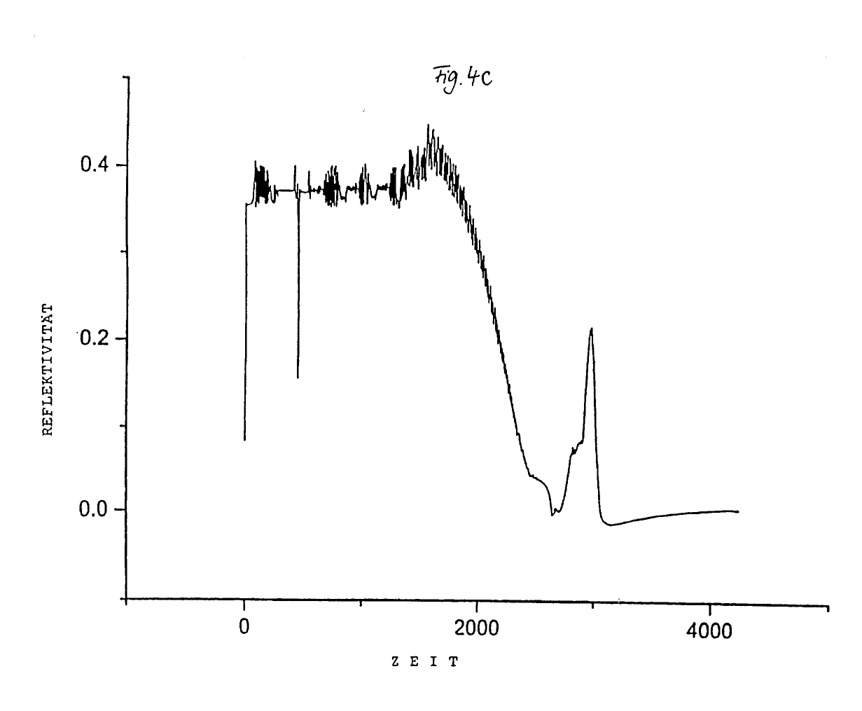

FIGS. 4a, b, c show exemplary reflectivity measurements of GaN on an Si wafer. The following layer structure and parameters apply to FIG. 4a:

GaN:Si=15 min; 200 mbar; 1170° C.; V/III=813

Nucl.:AlN=30 min; 200 mbar; 560° C.; V/III=1280

The following layer structure and parameters apply to FIG. 4b:

GaN=30 min; 50 mbar; 1170° C.; V/III=813

Nucl.:GaN=15 min; 500 mbar; 560° C.; V/III=8191

The following layer structure and parameters apply to FIG. 4c:

GaN=15 min; 50 mbar; 1170° C.; V/III=813

Nucl.:AlGaN=15 min; 500 mbar; 560° C.; V/III=096

The reference numerals in FIG. 3 correspond to those in the preceding FIGS. 1 and 2.

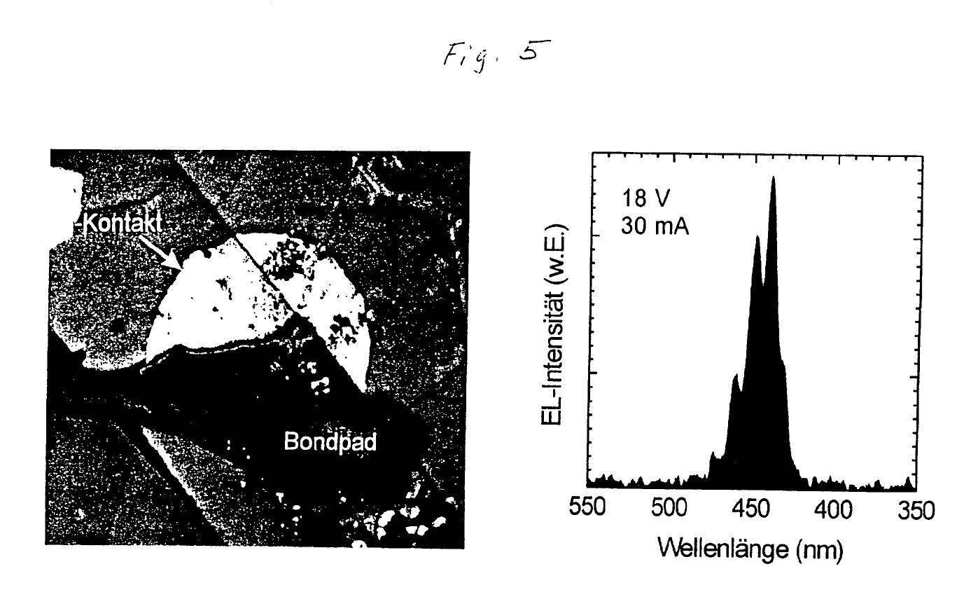

FIG. 5 shows by way of example a photo of a GaN LED on silicon and a measured spectrum of the light emission. List of abbreviations of the patent application

Al aluminum

As arsenic

BN boron nitride

C carbon

ELO, ELOG Epitaxial Lateral Overgrowth

Ga gallium

group III elements from the third main group of the periodic system of elements

group V elements from the fifth main group of the periodic system of elements apart from nitrogen

group III-V compound semiconductors comprising elements of the third and fifth main groups of the periodic system of elements apart from nitrogen

group III-N compound semiconductors comprising elements of the third main group of the periodic system of elements with nitrogen

group III-V-N compound semiconductors comprising elements of the third main group of the periodic system of elements with nitrogen and a further element of the fifth main group of the periodic system of elements

In indium

LED Light Emitting Device, Light Emitting Diode

LEO Lateral Epitaxial Overgrowth

MOCVD metal organic chemical vapor phase deposition in the present patent application interchangeable with

MOVPE metal organic vapor phase epitaxy and

HVPE hydride vapor phase epitaxy

N nitrogen

NH₃ ammonia

P phosphorus

sapphire Al₂O₃, aluminum oxide corundum is included here

Si silicon; as a substrate, not only customary Si substrates but also substrates such as, for example, silicon-on-insulator substrates are included

SiC silicon carbite

SiₓN_{y} silicon nitride (x, y are arbitrary)

SiO₂ silicon dioxide

### REFERENCE LIST OF CITATIONS

[Auner] G. W. Auner, F. Jin, V. M. Naik and R. Naik, Microstructure of low temperature grown AlN thin films on Si(111), J. Appl. Phys. 85, 7879 (1999)

[Duboz] J. Y. Duboz, Gallium Nitride as seen by the Industry, 3rd International Conference on Nitride Semiconductors (ICNS3), Mo_{—}01, Montpellier, France, Jul. 5-9, 1999

[Guha] S. Guha and N. A. Bojarczuk, Multicolored light emitters on silicon substrates, Appl. Phys. Lett. 73, 1487 (1998)

[Ito] Takahiro Ito, Kohyi Ohtsuka, Kazuhiro Kuwahara, Masatomo Sumiya, Yasushi Takano and Shunro Fuke, Effect of AlN buffer layer deposition conditions on the properties of GaN layer, J. Cryst. Growth 205, 20 (1999)

[Iwaya] Motoaki Iwaya, Tetsuya Takeuchi, Shigeo Yamaguchi, Christian Wetzel, Hiroshi Amano and Isamu Agaski, Reduction of etch pit density in organometallic vapor phase epitaxy-growth GaN on sapphire by insertion of a low-temperature-deposited buffer layer between-temperature-grown GaN, Jpn. J. Appl. Phys. 37, L316 (1998)

[Kawaguchi] Yashutoshi Kawaguchi, Shingo Nambu, Hiroki Sone, Masahito Yamaguchi, Hideto Miyake, Kazumasa Hiramatsu, Nobuhiko Sawaki, Yasushi Iyechika and Takayoshi Maeda, Selective area growth (SAG) and epitaxial lateral overgrowth (ELO) of GaN using tungsten mask, MRS Internet J. Nitride Semicond. Res. 4S1, G4.I.(1999)

[Kobayashi] N. P. Kobayashi, J. T. Kobayashi, P. D. Dapkus, W.-J. Choi, A. E. Bond, X. Zhang and H. D. Rich, GaN grown on Si (111) substrate using oxidized AlAs as an intermediate layer, Appl. Phys. Lett. 71, 3569(1987)

[Li] X. Li, S. G. Bishop and J. J. Coleman, GaN: From Selective Area Epitaxy to Epitaxial Lateral Overgrowth, MRS Internet J. Nitride Semicond. Res. 4S1, G4.8 (1999)

[Mayer] M. Mayer, A. Pelzmann, C. Kirchner, M. Schauler, F. Eberhard, M. Kamp, P. Unger, K. J. Ebeling, Device Performance of ultraviolet emitting diodes grown by MBE, J. Cryst. Growth 189/190, 782 (1998)

[Monemar] B. Monemar, Summary of the 3rd International Conference on Nitride Semiconductors (ICNS3), Montpellier, France, Jul. 5-9, 1999, MRS Internet J. Nitride Semicond. Res. Jul. 15, 1999

[Nikishin] S. A. Nikishin, N. N. Faleev, V. G. Antipov, S. Francoeur, L. Grave de Peralta, T. I. Prokofyeva, M. Holtz and S. N. G. Chu, High quality GaN grown on Si(111) by gas source molecular beam epitaxy with ammonia, Appl. Phys. Lett. 75, 2073 (1999)

[Sánchez-Garcia] M. A. Sánchez-Garcia, E. Calleja, E. Monroy, F. J. Sánchez, F. Calle, E. Muñoz, A. Sanz. Hervas, C. Villar and M. Aquilar, Study of high quality AlN layers grown on Si (111) substrates by plasma-assisted molecular beam epitaxy, MRS Internet J. Nitride Semicond. Res. 2, 33 (1997)

[Schenk] H. P. D. Schenk, G. D. Kipshidze, V. B. Lebedev, S. Shokhovets, R. Goldhahn, J. Kräuβlich, A. Fissel, Wo. Richter, Epitaxial growth of AlN and GaN on Si(111) by plasma-assisted molecular beam epitaxy, J. of Cryt. Growth 201/202, 359 (1999)

[Tran] Chuong A. Tran, A. Osinski, R. F. Karlicek Jr. and I. Berishev, Growth of InGaN/GaN multiple-quantum-well blue light-emitting diodes on silicon by metalorganic vapor phase epitaxy, Appl. Phys. Lett. 75, 1494 (1999)

[Wang] Lianshan Wang, Xianglin Liu, Yude Zan, Jun Wang, Du Wang, Da-cheng Lu and Zhanguo Wang, Wurtzite GaN epitaxial growth on a Si(001) substrate using γ-Al₂O₃ as an intermediate layer, Appl. Phys. Lett. 72, 109 (1998)

What is claimed is:

1. A method for producing group III-N, group III-V-N and metal-nitrogen component structures on SI substrates by means of organometallic vaporphase epitaxy, characterized by
the growth of a low-temperature seed layer and/or low-temperature buffer layer from a group III-V semiconductor and/or a metal-group V compound semiconductor and the component layer or sequence of layers from a group III-N, group III-V or metal-group V semiconductors in a horizontal growth chamber with a minimally possible lateral temperature difference of less than 1K, an adjustable ceiling temperature and/or wall temperature and on a substrate holder which is caused to rotate by a gas cushion, the gas inlets being configured in such a way that there is no unwanted interaction between the starting gases and, moreover, the procedure can be observed without disturbing the growth process, and at least one of the following points:
introducing one or more intermediate layers in the lower low-temperature and/or high-temperature buffer layer, not counted as belonging to the active part of the structure, consisting of the same material of the buffer but deposited at a different temperature and/or group III-V ratio and/or reactor pressure.
introducing intermediate layers in the lower low-temperature and/or high-temperature buffer layer, not counted as belonging to the active part of the structure, comprising layers of a different material of the group III-V and/or metal-group V compound semiconductors.

2. The method as claimed in claim 1, characterized by a check being kept on the layer growth or the layer smoothness and/or the layer thickness by measurement of the layer reflectivity.

3. The method as claimed in claim 1 or 2, characterized by the application of a metal and/or semiconductor layer on the SI substrate or a low-temperature buffer layer, in particular in conjunction with a subsequent conversion of such a layer to reduce the dislocation density and/or to reduce or avoid cracks in the epitaxial layer deposited on it.

4. The method as claimed in one of claims 1 to 3, characterized by partial masking of the substrate and/or of a low-temperature seed layer and/or low-temperature buffer layer and/or buffer layer with layers of insulators and/or thermally resistant materials such as SiO₂, SiₓN_{y}, C, BN and/or sapphire for example or, for example, metallic layers to eliminate dislocations and/or stresses in the grown layers or the substrate, in particular in the form of submonolayers to several monolayers of a metal on the substrate before the substrate before introducing the group V starting material.

5. The method as claimed in one of claims 1 to 4, characterized by applying one or more reflective layers on the SI substrate to increase the reflectivity when using the method for photonic components, in particular by singly or multiply applying partial masking on the epitaxial layer of a different refractive index than the surrounding material to increase the reflectivity when using the method for photonic components.

6. The method as claimed in claim 5, characterized by applying sequences of layers with a different refractive index by means of sputtering and/or epitaxial methods on the SI substrate before the growth of the component layers to improve the light yield in the case of photonic components or as Bragg mirrors to produce vertically light-emitting components.

7. The method as claimed in one of claims 4 to 6, characterized by the deposition of 3-dimensional structures, for example pyramids or cones or pyramids or truncated cones, or other 3-dimensional structures with heights of from a few nm to several nm for field-emitter structures, from GaN and (AlGaln)N.

8. The method as claimed in one of claims 1 to 12, characterized by applying in particular cubic p-conducting or n-conducting intermediate layers, for example of GaN, BP, BN or other compound semiconductor layers, between the silicon substrate and the active component and/or the use of a conducting, in particular p-conducting substrate.

9. A device for carrying out the method as claimed in one or more of the preceding claims, characterized by with a horizontal growth chamber with a gas inlet and with a susceptor, reactor ceiling and reactor walls, the temperature of which can be controlled there, in that above the susceptor a minimally possible lateral temperature difference of less than 5K, preferably 1K, a ceiling temperature and wall temperature can be adjusted, the susceptor having a substrate holder which is caused to rotate by a gas cushion, it being possible for a low-temperature seed layer and/or low-temperature buffer layer to be grown from a group III-V semiconductor and/or a metal-group V compound semiconductor and for the component layer or sequence of layers to be grown from group III-N, group III-V-N or metal-group V semiconductors in the growth chamber, the gas inlet system is formed in such a way that there is no undesired interaction between the starting gases, and observation devices being provided for observing the procedure without disturbing the growth process.
